(19) United States
(12) Patent Application Publication
(10) Pub. No.: US 2021/0028322 A1
(43) Pub. Date: Jan. 28, 2021

(54) PHOTOELECTRIC CONVERSION MODULE AND METHOD FOR MANUFACTURING PHOTOELECTRIC CONVERSION MODULE

(71) Applicant: IDEMITSU KOSAN CO., LTD., Tokyo (JP)

(72) Inventors: Nobutaka YONEYAMA, Tokyo (JP); Mikio HAMANO, Tokyo (JP); Yoshihide MIYAGAWA, Tokyo (JP); Toshiaki YAMAURA, Tokyo (JP); Manabu TANAKA, Tokyo (JP); Akihiko ASANO, Tokyo (JP)

(73) Assignee: IDEMITSU KOSAN CO., LTD., Tokyo (JP)

(21) Appl. No.: 16/647,160

(22) PCT Filed: Sep. 4, 2018
(86) PCT No.: PCT/JP2018/032774

§ 371 Date: Mar. 13, 2020

(30) Foreign Application Priority Data
Sep. 15, 2017 (JP) 2017-178367

(51) Int. Cl. H01L 31/0224; H01L 31/18

(52) U.S. Cl. CPC H01L 31/022466; H01L 31/1884

(57) ABSTRACT

A photoelectric conversion module (10) comprises a photoelectric conversion cell (12) including a first electrode layer (22), a second electrode layer (24), and a photoelectric conversion layer (26); and a plurality of grid electrodes (31). At least one of the first electrode layer and the second electrode layer is a transparent electrode layer. The transparent electrode layer includes a first region and a second region. The second region has sheet resistance smaller than sheet resistance in the first region, a film thickness larger than a film thickness in the first region, or transmittance smaller than transmittance in the first region. An interval between the grid electrodes adjacent to each other in the first direction in the first region is smaller than an interval between the grid electrodes adjacent to each other in the first direction in the second region.

### TECHNICAL FIELD

The present invention relates to a photoelectric conversion module having a grid electrode and a method for manufacturing the photoelectric conversion module.

### BACKGROUND ART

A photoelectric conversion module such as a solar battery module including a plurality of photoelectric conversion cells is known (following Patent Literature 1). In an integrated thin-film photoelectric conversion module as described in Patent Literature 1, a photoelectric conversion cell includes a transparent electrode layer located on a light receiving surface, a rear surface electrode layer located on a surface opposite to the light receiving surface, and a photoelectric conversion layer between the transparent electrode layer and the rear surface electrode layer.

An electric resistance value of the transparent electrode layer is generally higher than an electric resistance value of an opaque electrode layer made of metal. Therefore, when a current generated by the photoelectric conversion flows through the transparent electrode layer, a power loss occurs due to the electric resistance value of the transparent electrode layer. In order to reduce the power loss in the transparent electrode layer, a grid electrode (collecting electrode) made of a thin line metal is provided on the transparent electrode layer in some cases.

In the photoelectric conversion module described in Patent Literature 1, the path of the current flowing through the transparent electrode layer is shortened by collecting the current flowing through the transparent electrode layer into the grid electrode. Therefore, power loss due to the electric resistance value of the transparent electrode layer can be reduced. However, since the grid electrode is generally non-transparent, it blocks light incident on the photoelectric conversion layer. Therefore, the short-circuit current (Isc) generated in the photoelectric conversion cell decreases due to the decrease in the light reaching the photoelectric conversion layer.

Accordingly, it is desired to balance both solving the problem of power loss due to the electric resistance value of the transparent electrode layer and solving the problem of reduction of short-circuit current due to light shielding by the grid electrode.

### CITATION LIST

### Patent Literature

Patent Literature 1: JP 2011-103425 A

### SUMMARY

A photoelectric conversion module according to one aspect comprises: a photoelectric conversion cell including a first electrode layer, a second electrode layer, and a photoelectric conversion layer between the first electrode layer and the second electrode layer; and a plurality of grid electrodes arrayed in a first direction in the photoelectric conversion cell, the plurality of grid electrodes extending in a direction intersecting the first direction, wherein at least one of the first electrode layer and the second electrode layer is a transparent electrode layer, the transparent electrode layer includes a first region and a second region, the second region has sheet resistance smaller than sheet resistance in the first region, a film thickness larger than a film thickness in the first region, or transmittance smaller than transmittance in the first region, and an interval between the grid electrodes adjacent to each other in the first direction in the first region is smaller than an interval between the grid electrodes adjacent to each other in the first direction in the second region.

A method for manufacturing a photoelectric conversion module according to one aspect comprises: a cell forming of forming a band-shaped photoelectric conversion cell including a first electrode layer, a second electrode layer, and a photoelectric conversion layer between the first electrode layer and the second electrode layer on a substrate, at least one of the first electrode layer and the second electrode layer being a transparent electrode layer; measuring sheet resistance, a film thickness or transmittance of the transparent electrode layer; and a grid forming step of forming a plurality of grid electrodes arrayed in a first direction in the photoelectric conversion cell, the plurality of grid electrodes extending in a direction intersecting the first direction, wherein, the plurality of grid electrodes are formed in the grid forming step such that a region having larger sheet resistance, a region having a smaller film thickness, or a region having larger transmittance has a smaller interval between grid electrodes.

### BRIEF DESCRIPTION OF DRAWINGS

FIG. 1 is a schematic top view of a photoelectric conversion module according to a first embodiment.

FIG. 2 is a schematic top view of the photoelectric conversion module in a region 2R in FIG. 1.

FIG. 3 is a schematic cross-sectional view of the photoelectric conversion module taken along line 3A-3A in FIG. 2.

FIG. 4 is a schematic perspective view of the photoelectric conversion module in a region 4R in FIG. 2.

FIG. 5 is a schematic cross-sectional view of the photoelectric conversion module taken along line 5A-5A in FIG. 1.

FIG. 6 is a schematic top view of the photoelectric conversion module in a region 6R in FIG. 1.

FIG. 7 is a schematic top view of the photoelectric conversion module in a region 7R in FIG. 1.

FIG. 8 is a schematic top view of a connection portion between a first grid electrode and a second grid electrode according to a first modification.

FIG. 9 is a schematic top view of a connection portion between a first grid electrode and a second grid electrode according to a second modification.

FIG. 10 is a schematic top view of a connection portion between a first grid electrode and a second grid electrode according to a third modification.

FIG. 11 is a schematic cross-sectional view illustrating a cell forming step in a method for manufacturing a photoelectric conversion module.

FIG. 12 is a schematic view illustrating a first grid forming step of forming a first grid electrode.

FIG. 13 is a schematic view illustrating a second grid forming step of forming a second grid electrode.

FIG. 14 is a schematic view illustrating one step of a step of forming a wire.

FIG. 15 is a schematic view illustrating steps subsequent to FIG. 14.

FIG. 16 is a schematic view illustrating a step of cutting out a part of the photoelectric conversion module.

### DESCRIPTION OF EMBODIMENTS

Hereinafter, embodiments will be described with reference to the drawings. In the drawings, the same or similar parts are denoted by the same or similar reference numerals. However, it should be noted that the drawings are schematic and ratios or the like of dimensions may be different from actual ones.

### First Embodiment

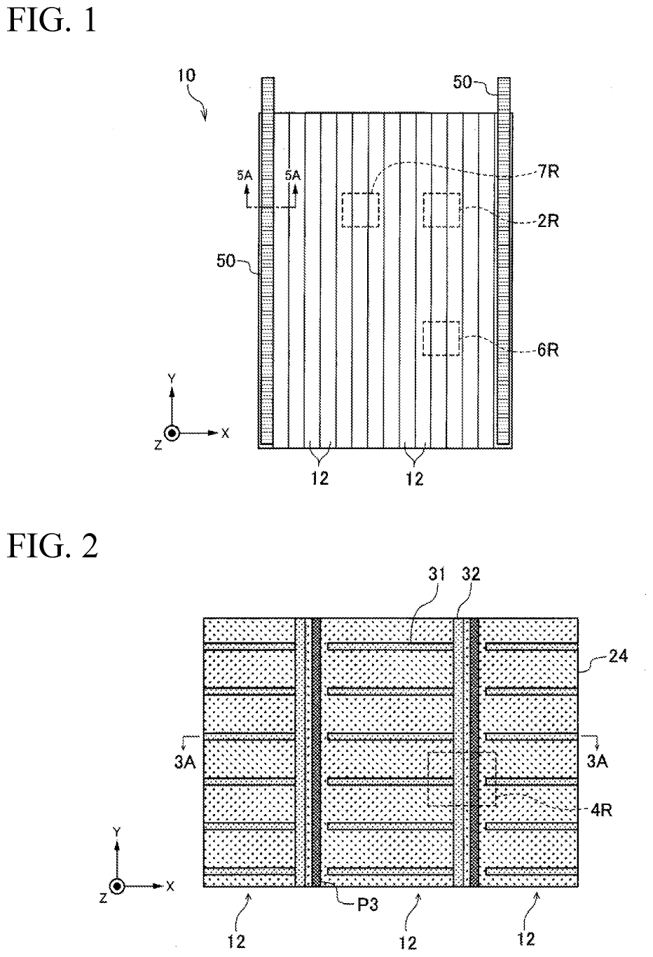

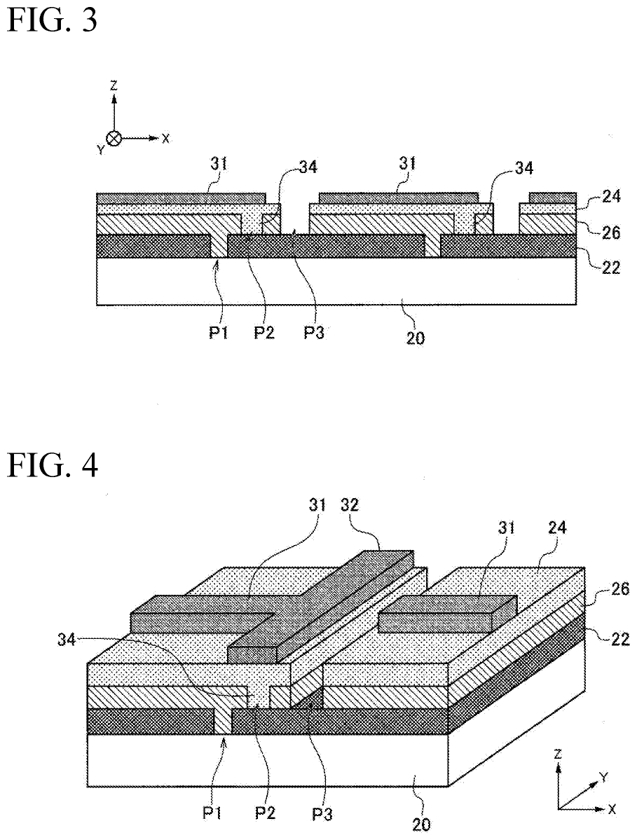

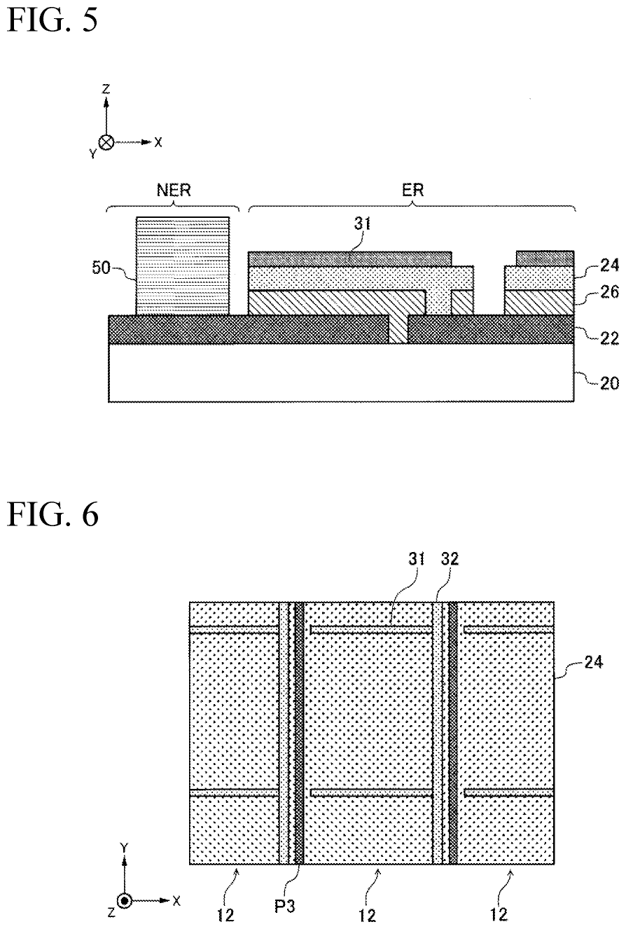

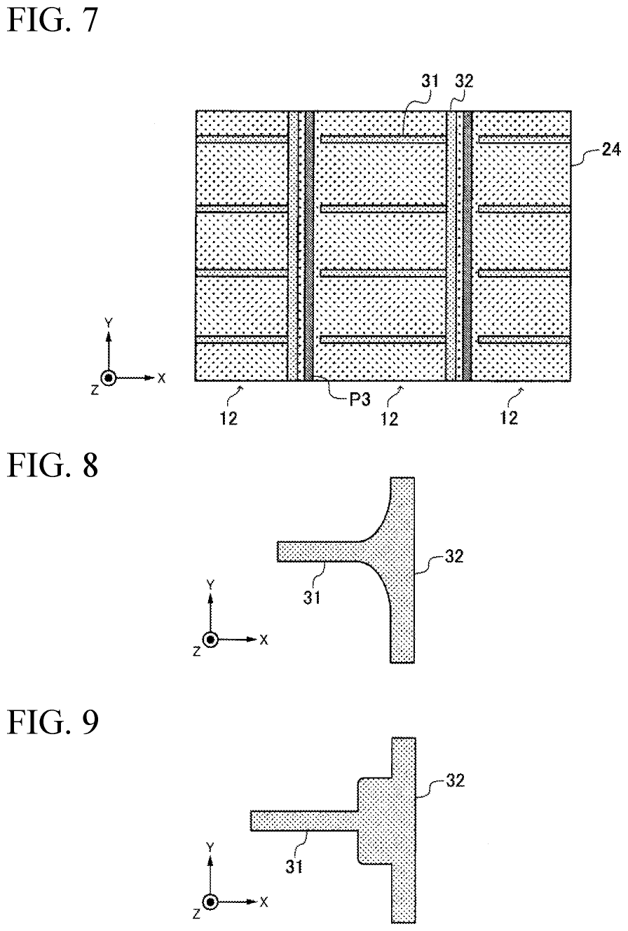

FIG. 1 is a schematic top view of a photoelectric conversion module according to a first embodiment. FIG. 2 is a schematic top view of the photoelectric conversion module in a region 2R in FIG. 1. FIG. 3 is a schematic cross-sectional view of the photoelectric conversion module taken along line 3A-3A in FIG. 2. FIG. 4 is a schematic perspective view of the photoelectric conversion module in a region 4R in FIG. 2. FIG. 5 is a schematic cross-sectional view of the photoelectric conversion module taken along line 5A-5A in FIG. 1 FIG. 6 is a schematic top view of the photoelectric conversion module in a region 6R in FIG. 1. FIG. 7 is a schematic top view of the photoelectric conversion module in a region 7R in FIG. 1.

A photoelectric conversion module 10 according to the present embodiment may be an integrated thin-film photoelectric conversion module including a plurality of photoelectric conversion cells 12 integrated on a substrate 20. Preferably, the photoelectric conversion module 10 is a solar cell module that converts light energy into electric energy. The substrate 20 may be made of, for example, glass, ceramics, resin, metal, or the like.

The photoelectric conversion cell 12 may have a substantially band shape when viewed from a direction orthogonal to a main surface of the substrate 20. Each of the photoelectric conversion cells 12 may extend long in a first direction (the Y direction in the drawing). The plurality of photoelectric conversion cells 12 are arranged side by side in a second direction (the X direction in the drawing) intersecting the first direction. The photoelectric conversion cells 12 adjacent to each other may be divided from each other by division parts P1, P2, P3 extending in the first direction.

Each of the photoelectric conversion cells 12 may include at least a first electrode layer 22, a second electrode layer 24 and a photoelectric conversion layer 26. The photoelectric conversion layer 26 is provided between the first electrode layer 22 and the second electrode layer 24. The first electrode layer 22 is provided between the photoelectric conversion layer 26 and the substrate 20. The second electrode layer 24 is located on opposite side of the photoelectric conversion layer 26 to the substrate 20.

In the present embodiment, the second electrode layer 24 may be formed of a transparent electrode layer. When the second electrode layer 24 is formed of a transparent electrode layer, light incident on the photoelectric conversion layer 26 or emitted from the photoelectric conversion layer 26 passes through the second electrode layer 24.

When the second electrode layer 24 is formed of a transparent electrode layer, the first electrode layer 22 may be formed of an opaque electrode layer or may be formed of a transparent electrode layer. In an example of a CIS-based photoelectric conversion module, it is preferable that the first electrode layer 22 is formed of a metal such as molybdenum, titanium or chromium, for example, from the viewpoint of corrosion resistance to Group VI elements.

In the present embodiment, as a preferred example, the second electrode layer 24 is formed of an n-type semiconductor, more specifically, a material having n-type conductivity, a wide bandgap, and relatively low resistance. The second electrode layer 24 may be made of, for example, zinc oxide (ZnO) added with a group III element or indium tin oxide (ITO). In this case, the second electrode layer 24 can function as both an n-type semiconductor and a transparent electrode layer.

The photoelectric conversion layer 26 may include, for example, p-type semiconductor. In an example of a CIS-based photoelectric conversion module, the photoelectric conversion layer 26 is formed of a compound semiconductor including a group I element (Cu, Ag, Au, or the like), a group III element (Al, Ga, In, or the like), and a group VI element (O, S, Se, Te, or the like). The photoelectric conversion layer 26 is not limited to those described above, and may be made of any material that causes photoelectric conversion.

It should be noted that the configuration of the photoelectric conversion cell 12 is not limited to the above-described embodiment, and can take various embodiments. For example, the photoelectric conversion cell 12 may have a configuration in which both an n-type semiconductor and a p-type semiconductor are sandwiched between the first electrode layer and the second electrode layer. In this case, the second electrode layer may not be formed of an n-type semiconductor. Furthermore, the photoelectric conversion cell 12 is not limited to a p-n junction structure, and may have a p-i-n junction structure including an intrinsic semiconductor layer (i-type semiconductor) between an n-type semiconductor and a p-type semiconductor.

The photoelectric conversion cell 12 may have a buffer layer (not illustrated) between the photoelectric conversion layer 26 and the second electrode layer 24. In this case, the buffer layer may be a semiconductor material having the same conductivity type as that of the second electrode layer 24 or a semiconductor material having a different conductivity type. It is sufficient that the buffer layer is made of a material having higher electric resistance than that of the second electrode layer 24. In an example of the CIS-based photoelectric conversion module, the buffer layer may be a Zn-based buffer layer, a Cd-based buffer layer or an In-based buffer layer. The Zn-based buffer layer may be, for example, ZnS, ZnO, Zn(OH) or ZnMgO, or a mixed crystal or a laminate thereof. The Cd-based buffer layer may be, for example, CdS, CdO or Cd(OH), or a mixed crystal or a laminate thereof. The In-based buffer layer may be, for example, InS, InO or In(OH), or a mixed crystal or a laminate thereof.

The first electrode layers 22 of the photoelectric conversion cells 12 adjacent to each other are electrically divided from each other by the division part P1. Similarly, the second electrode layers 24 of the photoelectric conversion cells 12 adjacent to each other are electrically divided from each other by the division part P3. The photoelectric conversion layers 26 of the photoelectric conversion cells 12 adjacent to each other are divided from each other by the division parts P2, P3.

The photoelectric conversion module 10 may have an electrical connection part 34 between the photoelectric conversion cells 12 adjacent to each other. The electrical connection part 34 electrically connects the photoelectric conversion cells 12 adjacent to each other in series. In the present embodiment, the electrical connection part 34 is formed by a portion continuous from the second electrode layer 24. In this case, the electrical connection part 34 may be made of the same material as that of the second electrode layer 24. Alternatively, the electrical connection part 34 may be made of a conductive material different from that of the second electrode layer 24. For example, the electrical connection part 34 may be made of the same material as that of the first grid electrode 31 or the second grid electrode 32 as described later.

The electrical connection part 34 extends in the thickness direction of the photoelectric conversion module 10 at the second division part P2, thereby electrically connecting the first electrode layer 22 of one photoelectric conversion cell 12 and the second electrode layer 24 of the other photoelectric conversion cell 12 to each other.

The photoelectric conversion module 10 has a plurality of first grid electrodes 31 arrayed in the first direction (the Y direction in the drawing) in each photoelectric conversion cell 12. Each first grid electrode 31 extends in the second direction (the X direction in the drawing) intersecting the first direction. The first grid electrode 31 may be provided on the second electrode layer 24 of each photoelectric conversion cell 12. The first grid electrode 31 may be made of a material having higher conductivity than that of the transparent electrode layer forming the second electrode layer 24. The first grid electrode 31 may be in direct contact with the transparent electrode layer. The width of the first grid electrode 31 in the first direction (the Y direction in the drawing) may be, for example, 5 to 100 μm. The thickness of the first grid electrode 31 may be, for example, 0.1 to 20 μm.

If necessary, the second grid electrode 32 extending in the first direction (the Y direction in the drawing) may be provided at an end of the first grid electrode 31 in the second direction (the X direction in the drawing). The second grid electrode 32 is coupled to the first grid electrode 31 at one end of the first grid electrode 31. The width of the second grid electrode 32 in the second direction (the X direction in the drawing) may be, for example, 5 to 200 μm. The thickness of the second grid electrode 32 may be, for example, 0.1 to 20 μm.

It is preferable that the thickness of at least one of the first grid electrode 31 and the second grid electrode 32 (or the electrical connection part 34) at the intersection of the first grid electrode 31 and the second grid electrode 32 (or the electrical connection part 34), preferably both of those is larger than the thickness of the first grid electrode 31 and the second grid electrode 32 (or the electrical connection part 34) at a position away from the intersection. For example, the thickness of the first grid electrode 31 may be gradually increased toward the intersection of the first grid electrode 31 and the second grid electrode 32 (or the electrical connection part 34). Further, the thickness of the second grid electrode 32 (or the electrical connection part 34) may be gradually increased toward the intersection of the first grid electrode 31 and the second grid electrode 32 (or the electrical connection part 34).

When light is applied to the photoelectric conversion layer 26 of each photoelectric conversion cell 12, an electromotive force is generated, and the first electrode layer 22 and the second electrode layer 24 become a positive electrode and a negative electrode, respectively. Therefore, a part of the free electrons generated in a certain photoelectric conversion cell 12 moves from the second electrode layer 24 to the first electrode layer 22 of the adjacent photoelectric conversion cell 12 directly through the electrical connection part 34. Further, another part of the free electrons generated in a certain photoelectric conversion cell 12 passes through the electrical connection part 34 from the second electrode layer 24 via the first grid electrode 31 and the second grid electrode 32, and moves to the first electrode layer 22 of the adjacent photoelectric conversion cells 12. As described above, free electrons generated in the photoelectric conversion cells 12 flow through the plurality of photoelectric conversion cells 12 in the second direction (the X direction in the drawing).

The photoelectric conversion module 10 has an electric wire 50 for supplying power to the photoelectric conversion module 10 or extracting power from the photoelectric conversion module 10. The wire 50 may be provided adjacent to the photoelectric conversion cell 12 located at the end of the photoelectric conversion module 10 in the second direction (the X direction in the drawing).

In the present embodiment, the transparent electrode layer forming the second electrode layer 24 may include a region 2R as illustrated in FIG. 2 and a region 6R as illustrated in FIG. 6. The region 2R and the region 6R are arranged in the same photoelectric conversion cell 12. The interval between the first grid electrodes 31 adjacent to each other in the first direction (Y direction) in the region 2R is smaller than the interval between the first grid electrodes 31 adjacent to each other in the first direction (Y direction) in the region 6R. Here, the region 6R of the second electrode layer 24 has sheet resistance smaller than the sheet resistance in the region 2R, a film thickness larger than the film thickness in the region 2R, or transmittance smaller than the transmittance in the region 2R. Note that the above-mentioned interval between the first grid electrodes 31 is an interval between a center line of an arbitrary first grid electrode 31 and a center line of an adjacent first grid electrode 31.

In the present embodiment, the second electrode layer 24 may further include a region 7R as illustrated in FIG. 7. The region 6R and the region 7R are arranged in different photoelectric conversion cells 12.

The interval between the first grid electrodes 31 adjacent to each other in the first direction (Y direction) in the region 7R is smaller than the interval between the first grid electrodes 31 adjacent to each other in the first direction (Y direction) in the region 6R. Here, the region 6R of the second electrode layer 24 has sheet resistance smaller than the sheet resistance in the region 7R, a film thickness larger than the film thickness in the region 7R, or transmittance smaller than the transmittance in the region 7R.

More preferably, the second electrode layer 24 of the photoelectric conversion module 10 has a distribution of the sheet resistance, film thickness or transmittance, and the interval between the first grid electrodes 31 adjacent to each other in the first direction (Y direction) is smaller as the sheet resistance is larger, smaller as the film thickness is smaller, or smaller as the transmittance is larger.

The distribution of the electric resistance value of the total of the transparent electrode layer and the first grid electrode 31 approaches uniform as the sheet resistance of the transparent electrode layer in a region is larger when the interval between the first grid electrodes 31 is narrowed in such a region. As described above, the overall sheet resistance is made nearly uniform, and the density of the first grid electrode 31 in an unnecessary region (area density of the grid electrode per unit area when the photoelectric conversion module is viewed in plan view) is reduced, so that it is possible to balance both solving the problem of power loss due to the electric resistance value of the transparent electrode layer and solving the problem of reduction of short-circuit current due to light shielding by the first grid electrode.

In general, it is considered that the smaller the film thickness of the transparent electrode layer, the higher the sheet resistance of the transparent electrode layer. Moreover, it is considered that the higher the transmittance of the transparent electrode layer, the higher the sheet resistance of the transparent electrode layer. It is considered that this is because when the transmittance of the transparent electrode layer is high, the film thickness of the transparent electrode layer is generally small or the carrier concentration of the transparent electrode layer is low.

Therefore, it is considered that, as the film thickness of the transparent electrode layer is smaller, or as the transmittance of the transparent electrode layer is larger, by narrowing the interval between the first grid electrodes 31, the distribution of the electric resistance value of the total of the transparent electrode layer and the first grid electrode 31 approaches uniform. Even in this case, the overall sheet resistance is made nearly uniform, and the density of the first grid electrode 31 in an unnecessary region is reduced, so that it is possible to balance both solving the problem of power loss due to the electric resistance value of the transparent electrode layer and solving the problem of reduction of short-circuit current due to light shielding by the first grid electrode.

The film thickness or transmittance of the transparent electrode layer can be more easily measured in a production line than the sheet resistance of the transparent electrode layer. Therefore, when the interval between the first grid electrodes 31 is set according to the film thickness or the transmittance of the transparent electrode layer, there is a high merit in manufacturing the photoelectric conversion module 10.

FIG. 8 is a schematic top view of a connection portion between the first grid electrode 31 and the second grid electrode 32 according to a first modification. In the first modification, the width of the first grid electrode 31 in the first direction (Y direction) increases as approaching the second grid electrode 32. Specifically, the width of the first grid electrode 31 in the first direction (Y direction) gradually increases as approaching the second grid electrode 32.

Conversely, the width of the second grid electrode 32 in the second direction (X direction) may gradually increase as approaching the first grid electrode 31.

FIG. 9 is a schematic top view of a connection portion between the first grid electrode 31 and the second grid electrode 32 according to a second modification. In the second modification, the width of the first grid electrode 31 in the first direction (Y direction) increases as approaching the second grid electrode 32. Specifically, the width of the first grid electrode 31 in the first direction (Y direction) increases as approaching the second grid electrode 32 step by step.

Conversely, the width of the second grid electrode 32 in the second direction (X direction) may gradually increase as approaching the first grid electrode 31 step by step.

In the first modification and the second modification, the region of the connection portion between the first grid electrode 31 and the second grid electrode 32 is increased, so that the electrical connection failure or increase in electric resistance at the connection portion between the first grid electrode 31 and the second grid electrode 32 can be suppressed.

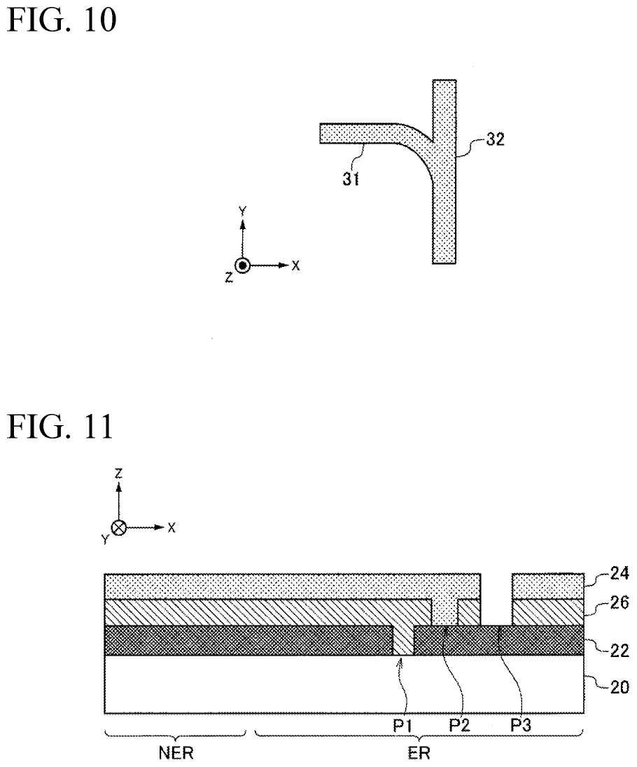

FIG. 10 is a schematic top view of the coupling portion between the first grid electrode 31 and the second grid electrode 32 according to a third modification. In the third modification, the first grid electrode 31 bends in the first direction (Y direction) as it approaches the second grid electrode 32. Since the coupling location between the first grid electrode 31 and the second grid electrode 32 is bent as described above, the reflection of the current flowing through the first grid electrode 31 at the coupling location can be reduced.

As another modification, the first grid electrode 31 may increase in thickness as it approaches the second grid electrode 32.

Next, with reference to FIGS. 11 to 16, a method for manufacturing a photoelectric conversion module according to an embodiment will be described. Note that, in the following steps, each layer can be appropriately formed by a film forming means such as a sputtering method or an evaporation method.

First, on the substrate 20, the band-shaped photoelectric conversion cell 12 including the first electrode layer 22, the second electrode layer 24, and the photoelectric conversion layer 26 between the first electrode layer 22 and the second electrode layer 24 is formed (cell forming step). Specifically, first, a material forming the first electrode layer 22 is formed on the substrate 20. The material constituting the first electrode layer 22 is formed in a region extending over the plurality of photoelectric conversion cells 12. The materials of the substrate 20 and the first electrode layer 22 are as described above. Next, a part of the material constituting the first electrode layer 22 is removed in a thin line shape to form a first division part P1 for forming the first electrode layer 22 into a plurality of band shapes. The removal of a part of the material constituting the first electrode layer 22 can be performed by a means such as a laser or a needle.

Next, a material forming the photoelectric conversion layer 26 is formed on the first electrode layer 22. The material of the photoelectric conversion layer 26 is as described above. At this time, the material forming the photoelectric conversion layer 26 may be filled also in the first division part P1. Alternatively, the first division part P1 may be filled with another insulating member different from the material forming the photoelectric conversion layer 26. Next, a part of the material constituting the photoelectric conversion layer 26 is removed in a thin line shape to form a second division part P2 for forming the photoelectric conversion layer 26 into a plurality of band shapes.

Next, a material constituting of the second electrode layer 24 is formed on the photoelectric conversion layer 26. The material of the second electrode layer 24 is as described above. In the present embodiment, the second electrode layer 24 is preferably a transparent electrode layer. The material forming the second electrode layer 24 may be filled also in the second division part P2. The second electrode layer 24 filled also in the second division part P2 constitutes the above-described electrical connection part 34. Alternatively, the inside of the second division part P2 may be filled with another conductive material different from the material forming the second electrode layer 24. Next, a part of the material constituting the second electrode layer 24 and the photoelectric conversion layer 26 is removed in a thin line shape to form a third division part P3 for forming the second electrode layer 24 and the photoelectric conversion layer 26 into a plurality of band shapes.

The method for manufacturing the photoelectric conversion module may include a step of measuring the sheet resistance, film thickness, or transmittance of the transparent electrode layer forming the second electrode layer 24. The sheet resistance of the transparent electrode layer can be measured by, for example, a four-terminal resistance measuring instrument or a resistance measuring instrument utilizing the Hall effect. The film thickness of the transparent electrode layer can be measured by, for example, a spectrophotometer, a light interference type film thickness meter, SEM (a scanning electron microscope), a step meter, or a laser microscope. The transmittance of the transparent electrode layer can be measured by, for example, a spectrophotometer.

The measurement of the sheet resistance, film thickness, or transmittance of the transparent electrode layer may be performed on a photoelectric conversion module used as a finished product, on a dummy photoelectric conversion module not used as a finished product, or on a dummy glass substrate. When the photoelectric conversion module 10 is mass-produced, the distribution of the sheet resistance, film thickness, or transmittance of the transparent electrode layer is substantially the same between products in the same production line (or lot). Therefore, a product not used as a finished product, for example, a semi-finished product formed on the substrate 20 up to the photoelectric conversion layer 26, or a dummy glass substrate on which a transparent electrode layer is formed may be taken out, and the sheet resistance, film thickness, or transmittance of the transparent electrode layer for the taken-out semi-finished product or the dummy glass substrate may be measured. This makes it possible to estimate the sheet resistance, film thickness, or transmittance of the transparent electrode layer of the photoelectric conversion module 10 used as a product in the same production line (or lot).

The method for manufacturing the photoelectric conversion module may include a grid forming step of forming grid electrodes 31, 32 after the cell forming step. The grid forming step may include a first grid forming step and a second grid forming step. The first grid forming step may be performed at any timing before or after the second grid forming step. The grid forming step may be performed before the third division part P3 is formed.

In the first grid forming step, a plurality of first grid electrodes 31 provided arrayed in the photoelectric conversion cell 12 in the first direction (the Y direction in the drawing) and extending in the second direction (the X direction in the drawing) intersecting the first direction are formed. In the second grid forming step, the second grid electrode 32 extending in the first direction (the Y direction in the drawing) as described above is formed.

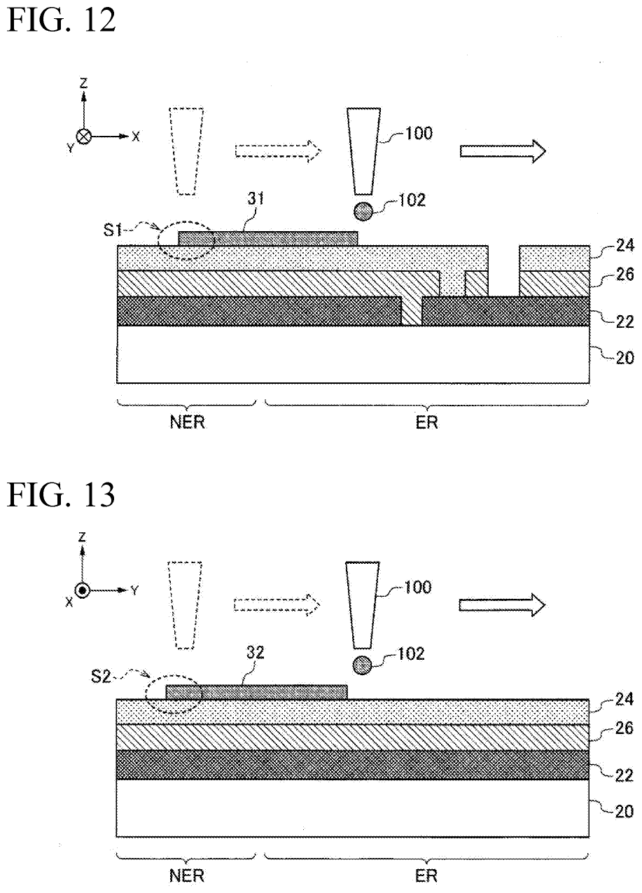

The first grid electrode 31 and/or the second grid electrode 32 can be formed by, for example, inkjet printing, screen printing, gravure offset printing, or flexographic printing. Hereinafter, an example in a case where the first grid electrode 31 and the second grid electrode 32 are formed by applying a conductive ink, for example, inkjet printing will be described with reference to FIGS. 12 and 13.

A conductive ink 102 may be formed of a conductive paste containing conductive particles such as silver and copper, an organic solvent, and a dispersant. The conductive ink 102 may include a binder as needed. The conductive ink 102 is formed on the second electrode layer 24 by being discharged from the nozzle 100. The conductive ink 102 is preferably fired after being applied. By firing the conductive ink 102, the organic solvent and the dispersant are vaporized, and the conductive particles remain in a predetermined application pattern. As a result, the first grid electrode 31 and the second grid electrode 32 are formed.

In an example, the firing temperature of the conductive ink 102 may be in the range of 100° C. to 200° C. In the case of the above-described CIS-based photoelectric conversion module, the firing temperature of the conductive ink 102 is preferably 150° C. or lower in order to suppress the deterioration and destruction of the photoelectric conversion cells constituting the CIS-based photoelectric conversion module. The firing of the conductive ink 102 is more preferably performed in the air (more preferably, in dry air) or in a nitrogen atmosphere. The firing time may be within a range from 5 to 60 minutes, for example.

Preferably, in the first grid forming step, a start point S1 at which the application of the conductive ink 102 is started in one photoelectric conversion module is located in a non-effective region NER which does not contribute to the electromotive force of the photoelectric conversion module (see FIG. 12). Specifically, as illustrated in FIG. 12, while the nozzle 100 of the inkjet head is moved in the second direction (X direction) from the start point S1, the conductive ink 102 is discharged from the nozzle 100, so that the conductive ink 102 is formed along the second direction.

In the second grid forming step, it is preferable that a start point S2 at which the application of the conductive ink 102 is started in one photoelectric conversion module is located in a non-effective region NER which does not contribute to the electromotive force of the photoelectric conversion module (see FIG. 13). Specifically, as illustrated in FIG. 13, while the nozzle 100 of the inkjet head is moved in the first direction (Y direction) from the start point S2, the conductive ink 102 is discharged from the nozzle 100, so that the conductive ink 102 is formed along the second direction.

The above-described non-effective region NER is defined by a region which does not contribute to photoelectric conversion during a stage of manufacture or after completion of a product. The non-effective region NER may be, for example, a region in which the at least the second electrode layer 24 is cut out, a region that does not contribute to the photoelectric conversion separated by cutting out of the first electrode layer 22, the photoelectric conversion layer 26, and the second electrode layer 24 from the photoelectric conversion cells 12 that contribute to photoelectric conversion, or a region cut out from the photoelectric conversion module 10 being manufactured.

When the photoelectric conversion module is mass-produced, there may be a period (lead time) in which the conductive ink 102 is not applied before starting the ink application to the start points S1, S2. If the conductive ink 102 dries during this period, the conductive ink 102 may not be accurately applied to the start points S1, S2. In the present embodiment, since the start points S1, S2 are located in the non-effective region NER, the performance of the photoelectric conversion module is hardly affected even if the conductive ink 102 is not accurately applied to the start points S1, S2.

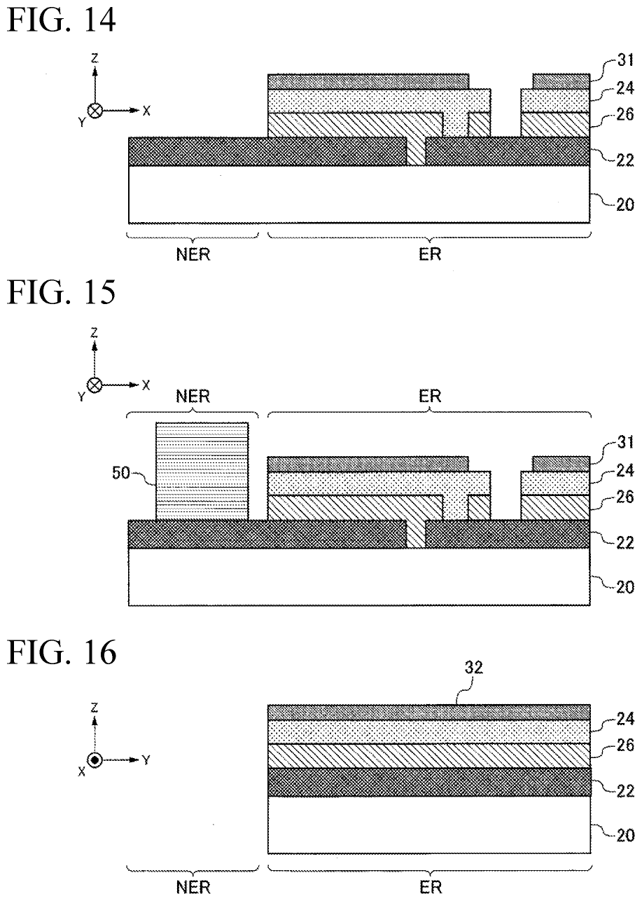

In a specific example, the method for manufacturing the photoelectric conversion module may include a step of removing at least a part of the second electrode layer 24, preferably the second electrode layer 24 and the photoelectric conversion layer 26, as illustrated in FIG. 14. In the region from which at least the second electrode layer 24 has been removed constitutes the non-effective region NER. The start point S1 at which the application of the conductive ink 102 is started may be located in the non-effective region NER.

Further, as illustrated in FIG. 15, the above-described wire 50 may be formed in a region where at least the second electrode layer 24 has been removed. In this case, the region from which at least the second electrode layer 24 has been removed may be an end region of the photoelectric conversion module 10 in the second direction (X direction).

In a specific example, as illustrated in FIG. 16, the method for manufacturing a photoelectric conversion module may further include a step of cutting out a region including the start point S2 at which application of the conductive ink 102 is started.

As described above, the photoelectric conversion module 10 described in the first embodiment is obtained. In FIGS. 14, 15 of the above embodiment, at least the second electrode layer 24 at a location corresponding to the non-effective region NER is removed. The present invention is not limited to this, and the wire 50 may be formed on the second electrode layer 24 without removing the second electrode layer 24. In this case, a division groove for dividing the non-effective region NER and the effective region ER contributing to photoelectric conversion may be formed between the wire 50 and the photoelectric conversion cell 12 adjacent to the wire 50. This division groove can be formed, for example, by removing the first electrode layer 22, the photoelectric conversion layer 26, and the second electrode layer 24.

As described above, the contents of the present invention have been disclosed through the embodiments. However, it should not be understood that the description and drawings forming a part of the present disclosure limit the present invention. From this disclosure, various alternative embodiments, examples, and operation techniques will be apparent to those skilled in the art. Therefore, the technical scope of the present invention is determined only by the matters specifying the invention according to the claims that are appropriate from the above description.

For example, the photoelectric conversion module 10 may be sealed with a transparent sealing material not illustrated.

In the illustrated embodiment, the first grid electrode 31 and the second grid electrode 32 are provided on the second electrode layer 24. Alternatively, the first grid electrode 31 and the second grid electrode 32 may be provided between the photoelectric conversion layer 26 and the second electrode layer 24. In this case, it is preferable that the first grid electrode 31 and the second grid electrode 32 are not in direct contact with the photoelectric conversion layer 26 and are located to be separated from the photoelectric conversion layer 26. By covering the first grid electrode 31 and the second grid electrode 32 with the second electrode layer 24, it is possible to suppress connection failure between the second electrode layer 24 (transparent electrode layer) and the grid electrodes 31, 32. As a result, an increase in the contact resistance between the grid electrodes 31, 32 can be suppressed, and a decrease in the conversion efficiency of photoelectric conversion can be suppressed.

In the above-described embodiment, the second electrode layer 24 is formed of a transparent electrode layer. Alternatively, the first electrode layer 22 may be constituted by a transparent electrode layer. In this case, the second electrode layer 24 may be formed of a transparent electrode layer or may be formed an opaque electrode layer. Moreover, in this case, the first grid electrode 31 and the second grid electrode 32 are preferably provided adjacent to the first electrode layer 22. In this case, the substrate 20 may be formed of a transparent substrate.

In the illustrated embodiment, all the first grid electrodes 31 have the same length in the second direction (X direction). Alternatively, the lengths of the first grid electrodes 31 in the second direction (X direction) may be different within the same photoelectric conversion cell 12 or between different photoelectric conversion cells 12. For example, a first grid electrode that is long in the second direction (X direction) and a first grid electrode that is short in the second direction (X direction) may be arranged in a predetermined pattern in the first direction (Y direction).

Further, in the present embodiment, the thin-film photoelectric conversion module having the integrated structure (having the division parts P1 to P3) has been described as an example. However, the present invention is not limited to this, and the present invention is also applicable to a photoelectric conversion module having no integrated structure, in other words, having no division parts P1 to P3. Specifically, in a photoelectric conversion module having no integrated structure, the interval at which grid electrodes are formed may be determined according to the sheet resistance, film thickness, and transmittance of the transparent electrode layer provided in the photoelectric conversion module.

It should be noted that the terms “first”, “second”, and “third” in the present specification are used to distinguish each term in this specification, and the term “first”, “second,” and “third” in the specification do not necessarily correspond to the terms “first,” “second,” and “third” in the claims.

The entire contents of Japanese Patent Application No. 2017-178367 filed on Sep. 15, 2017 are incorporated herein by reference.

### INDUSTRIAL APPLICABILITY

According to the above embodiment, it is possible to suppress a power loss due to the electric resistance value of the transparent electrode layer and to suppress a reduction in short-circuit current due to light shielding by the grid electrode.

### REFERENCE SIGNS LIST

10 Photoelectric conversion module
12 Photoelectric conversion cell
20 Substrate
22 First electrode layer
24 Second electrode layer (n-type semiconductor)
26 Photoelectric conversion layer (p-type semiconductor)
31 First grid electrode
32 Second grid electrode
50 Wire

1. A photoelectric conversion module comprising:
a photoelectric conversion cell including a first electrode layer, a second electrode layer, and a photoelectric conversion layer between the first electrode layer and the second electrode layer; and
a plurality of grid electrodes arrayed in a first direction in the photoelectric conversion cell, the plurality of grid electrodes extending in a direction intersecting the first direction,
wherein at least one of the first electrode layer and the second electrode layer is a transparent electrode layer,
the transparent electrode layer includes a first region and a second region,
the second region has sheet resistance smaller than sheet resistance in the first region, a film thickness larger than a film thickness in the first region, or transmittance smaller than transmittance in the first region, and
an interval between the grid electrodes adjacent to each other in the first direction in the first region is smaller than an interval between the grid electrodes adjacent to each other in the first direction in the second region.

2. The photoelectric conversion module according to claim 1, wherein the first region and the second region are provided in the same photoelectric conversion cell.

3. The photoelectric conversion module according to claim 1, wherein the first region and the second region are provided in different photoelectric conversion cells.

4. The photoelectric conversion module according to claim 1,
wherein the transparent electrode layer has a distribution of the sheet resistance, the film thickness or the transmittance, and
the interval between the grid electrodes adjacent to each other in the first direction is smaller as the sheet resistance is larger, smaller as the film thickness is smaller, or smaller as the transmittance is larger.

5. A method for manufacturing a photoelectric conversion module, comprising:
cell forming of forming a band-shaped photoelectric conversion cell including a first electrode layer, a second electrode layer, and a photoelectric conversion layer between the first electrode layer and the second electrode layer on a substrate, at least one of the first electrode layer and the second electrode layer being a transparent electrode layer;
measuring sheet resistance, a film thickness or transmittance of the transparent electrode layer; and
a grid forming step of forming a plurality of grid electrodes arrayed in a first direction in the photoelectric conversion cell, the plurality of grid electrodes extending in a direction intersecting the first direction,
wherein, the plurality of grid electrodes are formed in the grid forming step such that a region having larger sheet resistance, a region having a smaller film thickness, or a region having larger transmittance has a smaller interval between grid electrodes.

6. The photoelectric conversion module according to claim 2,
wherein the transparent electrode layer has a distribution of the sheet resistance, the film thickness or the transmittance, and
the interval between the grid electrodes adjacent to each other in the first direction is smaller as the sheet resistance is larger, smaller as the film thickness is smaller, or smaller as the transmittance is larger.

7. The photoelectric conversion module according to claim 3,
wherein the transparent electrode layer has a distribution of the sheet resistance, the film thickness or the transmittance, and
the interval between the grid electrodes adjacent to each other in the first direction is smaller as the sheet resistance is larger, smaller as the film thickness is smaller, or smaller as the transmittance is larger.
